(19) United States
(12) Patent Application Publication
(10) Pub. No.: US 2013/0042914 A1
(43) Pub. Date: Feb. 21, 2013

(54) NOVEL DESIGN OF UPCONVERTING LUMINESCENT LAYERS FOR PHOTOVOLTAIC CELLS

(71) Applicants: Chung-Pui CHAN, Hong Kong (HK); Hsieh-Hsin Yeh, New Taipei City (TW)

(72) Inventors: Chung-Pui CHAN, Hong Kong (HK); Hsieh-Hsin Yeh, New Taipei City (TW)

(73) Assignee: Du Pont Apollo Limited, Hong Kong (HK)

(21) Appl. No.: 13/213,109

(22) Filed: Aug. 19, 2011

(51) Int. Cl. H01L 31/0232

(52) U.S. Cl. 136/257

(57) ABSTRACT

A solar cell including an upconverting luminescent material and a back reflecting layer is provided. The upconverting material can be located in any positions below the semiconductor layer of the solar cell. Therefore, the unabsorbed incident light, from the top direction, can be upconverted to light with shorter wavelengths and redirected by the back reflecting layer back to the semiconductor layer to increase the utilization rate of the incident light.

### BACKGROUND

1. Technical Field

The disclosure relates to photovoltaic cells. More particularly, the disclosure relates to the design of wavelength conversion layers for photovoltaic cells.

2. Description of Related Art

Photovoltaic cells (or solar cells) can efficiently absorb most of the lights with photon energies higher than the bandgap of the light-absorbing layers of the solar cells, but they would not absorb those photons of lesser energies. Therefore, a substantial portion of the incident solar light is unabsorbed and does not convert to electricity. Thus, making an efficient use of the unabsorbed solar light will play a key role in power improvement of solar cells.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one aspect, the present invention is directed to a solar cell for receiving an incident light from the top direction. The solar cell comprising at least an upconverting luminescent material and a back reflecting layer. The upconverting luminescent material is positioned below at least a semiconductor layer of the solar cell, such that the incident light, unabsorbed by the semiconductor layer, can be upconverted to a light with shorter wavelengths. The back reflecting layer can contain the upconverting luminescent material or be positioned below the upconverting luminescent material to redirect the light with shorter wavelengths back to the semiconductor layer.

According to an embodiment of this invention, the upconverting luminescent material comprises a rare earth metal ion, a dye, or a pigment.

According to another embodiment of this invention, the back reflecting layer can be a metal layer or an encapsulant layer containing a white pigment to redirect light.

Accordingly, since the unabsorbed incident light can be upconverted to the light with shorter wavelengths by the upconverting luminescent material and redirected back to the semiconductor layer by the back-reflecting layer for re-absorption, the utilization rate of the incident light can be further increased.

It is to be understood that both the foregoing general description and the following detailed description are by examples, and are intended to provide further explanation of the invention as claimed. Furthermore, many of the attendant features will be more readily appreciated as the same becomes better understood by reference to the following detailed description considered in connection with the accompanying drawings.

### BRIEF DESCRIPTION OF THE DRAWINGS

FIGS. 1A and 1B are cross-sectional diagrams of conventional photovoltaic cells.

FIGS. 2A-2B are cross-sectional diagrams of photovoltaic cells according to some embodiment of this invention.

FIGS. 3A-3D are cross-sectional diagrams of photovoltaic cells according to yet some other embodiments of this invention.

FIGS. 4A-4C are cross-sectional diagrams of photovoltaic cells according to yet some other embodiments of this invention.

FIGS. 5A-5C are cross-sectional diagrams of photovoltaic cells according to yet some other embodiments of this invention.

### DETAILED DESCRIPTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples. Furthermore, wherever possible, the same reference numbers are used in the drawings and the description to refer to the same or like parts.

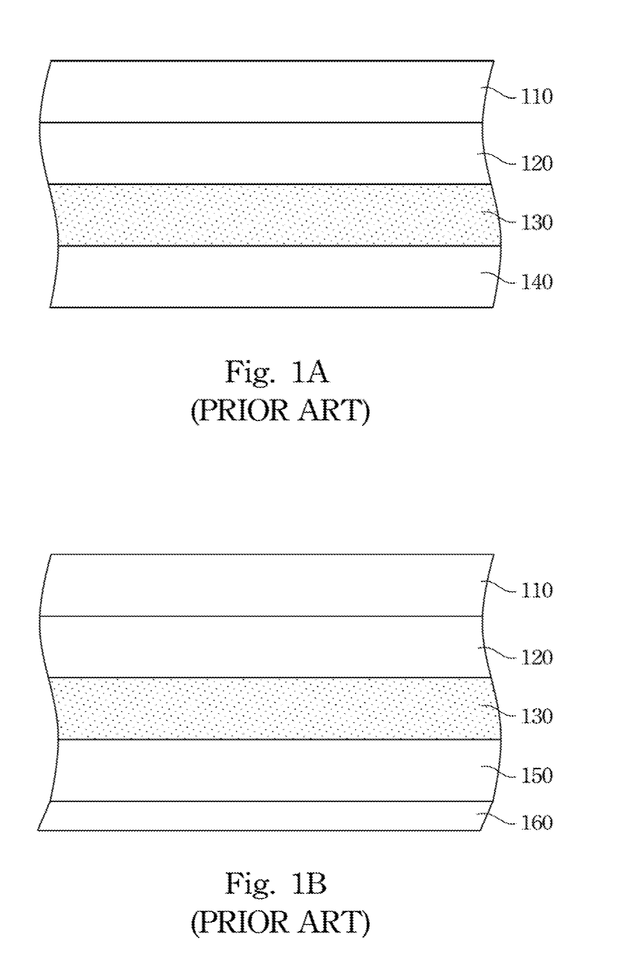

FIGS. 1A and 1B are cross-sectional diagrams of conventional photovoltaic cells. The photovoltaic cell in FIG. 1A sequentially has a transparent substrate 110, a transparent conductive layer 120, a semiconductor layer 130, and a metal electrode layer 140, from top to bottom. In this photovoltaic cell, the semiconductor layer 130 is responsible for absorbing incident solar light and converts the incident solar light into electricity. The generated electricity is then conducted out and collected through the top and bottom electrodes of the photovoltaic cell.

Since the incident solar light comes from the top of the figure, the transparent conductive layer 120 serves as the top electrode of the photovoltaic cell. The metal electrode layer 140 serves as the bottom electrode of the photovoltaic cell and a back reflecting layer to redirect the incident solar light back to the semiconductor layer 130 to increase the utilization rate of the incident solar light.

The photovoltaic cell in FIG. 1B sequentially has a transparent substrate 110, a transparent conductive layer 120, a semiconductor layer 130, another transparent conductive layer 150, and a back reflecting layer 160, from top to bottom. The difference between the photovoltaic cells in FIGS. 1A and 1B is that the metal electrode layer in FIG. 1A is replaced by the transparent conductive layer 150 and the back reflecting layer 160 in FIG. 1B. In FIG. 1B, the transparent conductive layer 150 serves as the bottom electrode of the photovoltaic cell. The incident solar light is redirected by the back reflecting layer 160 to the semiconductor layer 130. In some cases, if the difference between the refractive indexes of the semiconductor layer 130 and the transparent conductive layer 150 is compatible, reflection of the incident light can occur at the interface between the semiconductor layer 130 and the transparent conductive layer 150. Then, the back reflecting layer 160 can be optional in these cases.

In both FIGS. 1A and 1B, the semiconductor layer 130 can be composed of a thin film or multiple thin films. When the semiconductor layer 130 has only a thin film, such as a CdTe thin film, a copper indium gallium selenide (CIGS) thin film, a polysilicon thin film, or an amorphous silicon thin film, to absorb a portion of the incident solar light, the photovoltaic cell is a single junction cell. When the semiconductor 130 has multiple thin films, such as a combination of a GaAs thin film, a Ge thin film, and a GaInP₂ thin film, to increase the absorbed portion of the solar light, the photovoltaic cell is a multijunction cell, which is also called as a tandem solar cell. Since only the photons with energy higher than the band gap of the each thin film in the semiconductor layer 130 can be absorbed, the various semiconductor thin films are arranged in an order of equivalent or decreasing band gap from the transparent substrate 110 to the metal electrode layer 140 in FIG. 1A or to the back reflecting layer 160 in FIG. 1B.

In both FIGS. 1A and 1B, the material of the transparent substrate 110 can be a transparent polymeric material, such as an acrylic resin or a polyamide, glass, or quartz. The transparent substrate 110 can be removed without affecting the function of the photovoltaic cells in FIGS. 1A and 1B.

In FIG. 1A, the material of the metal electrode layer 140 can be Al, Ag, Ti, or Cu, for example.

In both FIGS. 1A and 1B, the material of the transparent conductive layers 120 and 150 can be a metal oxide or a complex metal oxide. The metal oxides can be PbO₂, CdO, Tl₂O₃, Ga₂O₃, ZnPb₂O₆, CdIn₂O₄, MgIn₂O₄, ZnGaO₄, AgSbO₃, CuAlO₂, CuGaO₂, or CdO—GeO₂, for example. The complex metal oxide can be AZO (ZnO: Al), GZO (ZnO: Ga), GAZO (ZnO: Ga, Al), ATO (SnO₂: Sb), FTO (SnO₂: F), ITO (In₂O₃: Sn), BZO (BaO: Zr), or BaTiO₃, for example.

In FIG. 1B, the material of the back reflecting layer 160 can be a metal or a reflective encapsulant layer. The metal for the back reflecting layer 160 above can be Al, Ag, Ti, or Cu. The reflective encapsulant layer for the back reflecting layer 160 above can be an encapsulant material blended by a white pigment, such as DuPont PV5200 series of white reflective PVB (polyvinyl butyral) encapsulant sheets.

According to an aspect of this invention, a solar cell comprising an upconverting luminescent material and a back reflecting layer is provided. The incident solar light is from the top direction. Therefore, the upconverting luminescent material is positioned below at least one semiconductor thin film of the semiconductor layer, such as the semiconductor layer 130 of the solar cells in FIGS. 1A and 1B, to upconvert the unabsorbed incident light by the semiconductor layer to a light with shorter wavelengths.

Since the upconverting luminescent materials have been extensively documented, the upconverting luminescent material can be any available material containing rare earth ions, organic dyes, inorganic pigments, and/or semiconducting quantum dots, for example, to upconvert the unabsorbed incident light to the light with shorter wavelengths. Therefore, the method of forming the upconverting luminescent material can be sputtering, CVD, spray coating, spin-on coating, compounding etc. according to the used upconverting luminescent material.

According to an embodiment, the upconverting luminescent material can be yttrium oxide (Y₂O₃) doped with rare earth metal ions, such as Er³⁺ and/or Yb³⁺. According to another embodiment, the upconverting luminescent material can be a silicate glass doped with Tm³⁺. According to yet another embodiment, the upconverting luminescent material can be an II-VI semiconductor material, such as a metal sulfide, a metal selenide, or a metal telluride. According to yet another embodiment, the rare earth metal ions above can be Eu³⁺, Tb³⁺, Ce³⁺, Pr³⁺, Ho³⁺, Tm³⁺, Yb³⁺, or Er³⁺. According to yet another embodiment, the organic dye can be p-terphenyl, or pyrrolobenzodiazepine (PBD).

The back reflecting layer above can contain the upconverting luminescent material or be positioned below the upconverting luminescent material to redirect the light with the original and shorter wavelengths back to the semiconductor layer of the photovoltaic cell. Therefore, the back reflecting layer can be a metal layer, a reflective polymer sheet containing a white pigment, or any other suitable material combinations.

Accordingly, some exemplary embodiments of this invention are described as follow.

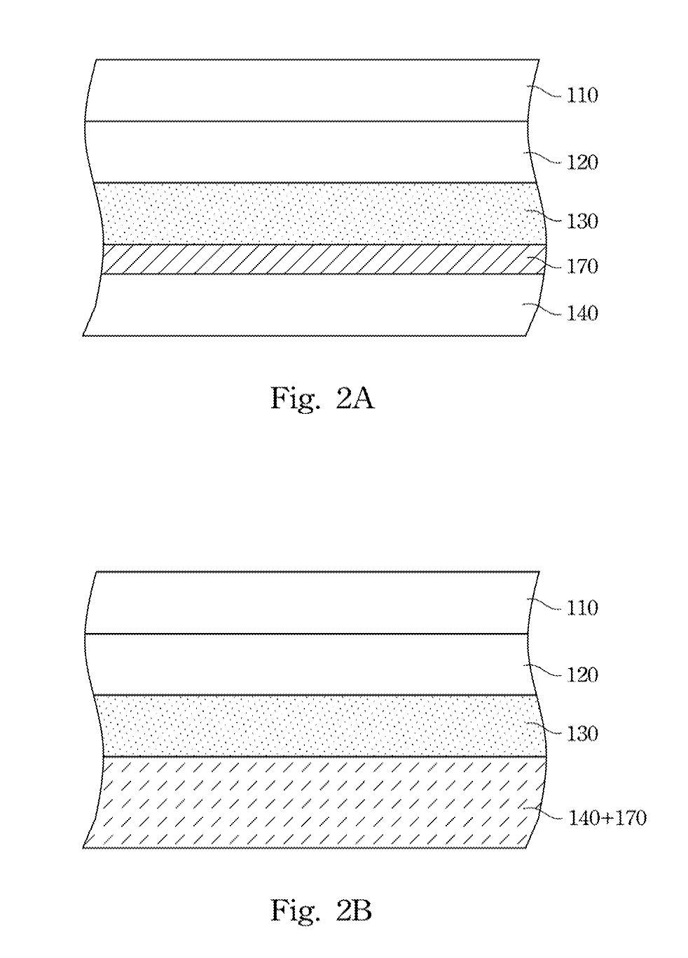

FIGS. 2A-2B are cross-sectional diagrams of photovoltaic cells according to some embodiment of this invention. In FIG. 2A, an upconverting luminescent material 170 is added between the semiconductor layer 130 and the metal electrode layer 140 of the photovoltaic cell's structure in FIG. 1A. In FIG. 2B, an upconverting luminescent material 170 is added to the metal electrode layer 140 of the photovoltaic cell's structure in FIG. 1A.

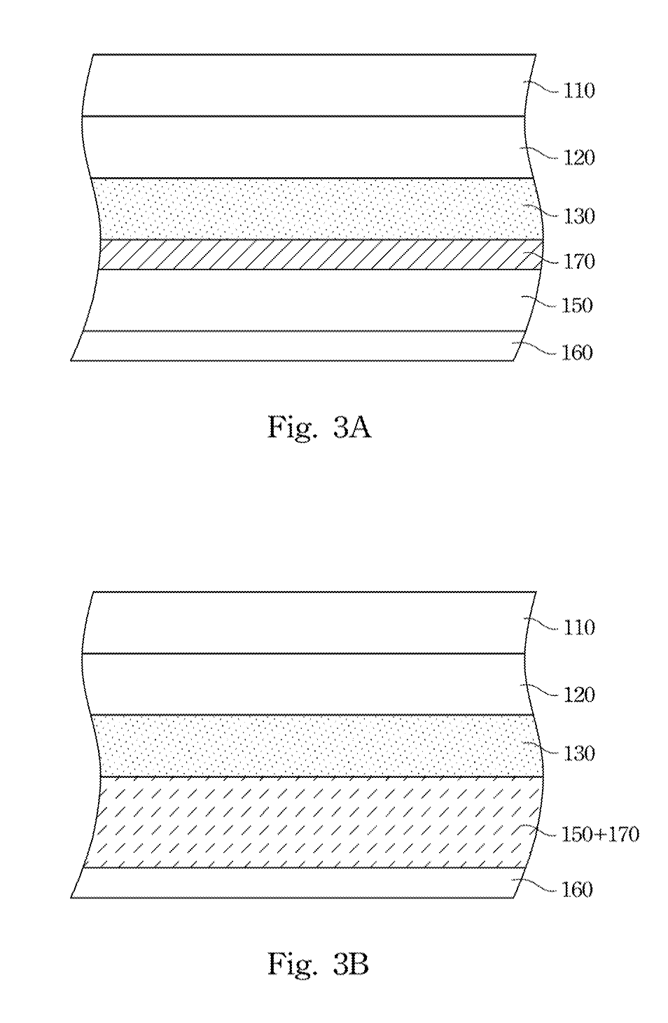

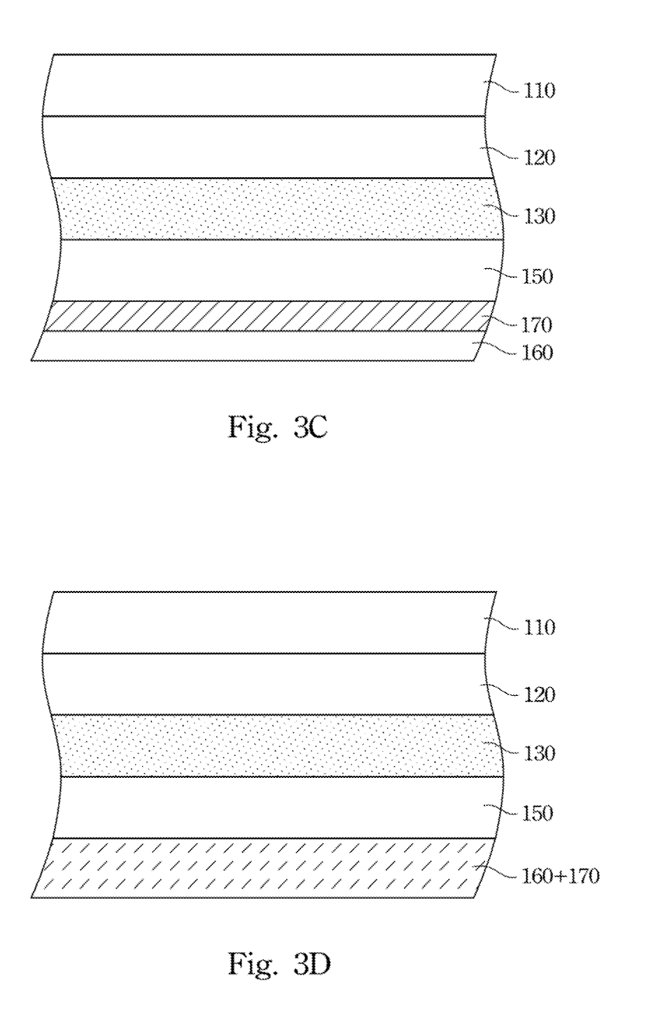

FIGS. 3A-3D are cross-sectional diagrams of photovoltaic cells according to some other embodiments of this invention. In FIGS. 3A-3D, the upconverting luminescent material 170 is added to the photovoltaic cell's structure in FIG. 1B, the only difference among the structures of FIGS. 3A-3D is the position of the upconverting luminescent material 170.

In FIG. 3A, the upconverting luminescent material 170 is between the semiconductor layer 130 and the transparent conductive layer 150. In FIG. 3B, the upconverting luminescent material 170 is added into the transparent conductive layer 150. In FIG. 3C, the upconverting luminescent material 170 is between the transparent conductive layer 150 and the back reflecting layer 170. In FIG. 3D, the upconverting luminescent material 170 is added into the back reflecting layer 160. According to some embodiments, the back reflecting layer 160 in FIGS. 3A-3D can be omitted, since the transparent conductive layer 150 still has some light redirecting function when the difference between the refractive indexes of the semiconductor layer 130 and the transparent conductive layer 150 is compatible.

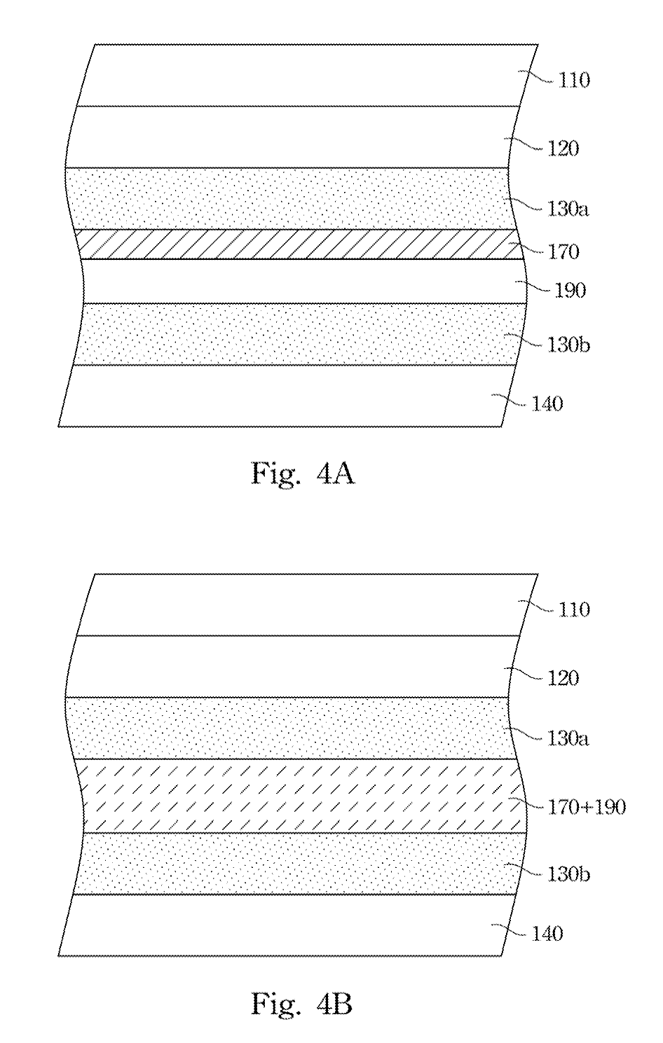

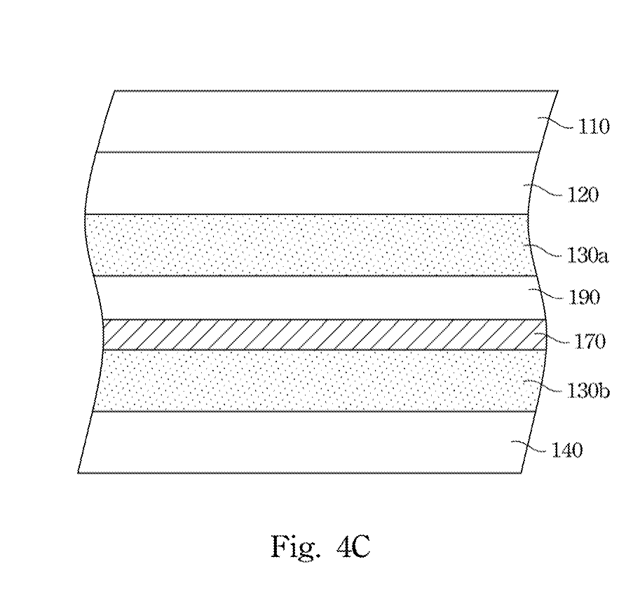

FIGS. 4A-4C are cross-sectional diagrams of photovoltaic cells according to some other embodiments of this invention. In FIGS. 4A-4C, the photovoltaic cells are multijunction cells, and the upconverting luminescent material 170 and a third transparent conductive layer 190 is positioned in the semiconductor layer 130 in FIG. 1A. Therefore, the semiconductor layers 130 in FIGS. 4A-4C are divided into a first semiconductor layer 130a and a second semiconductor layer 130b by the upconverting luminescent material 170 and a third transparent conductive layer 190. According to some embodiments, the upconverting luminescent material 170 can be positioned between the first semiconductor layer 130a and the third transparent conductive layer 190-(in FIG. 4A), in the third transparent conductive layer 190 (in FIG. 4B), or between the third transparent conductive layer 190 and the second semiconductor layer 130b (in FIG. 4C).

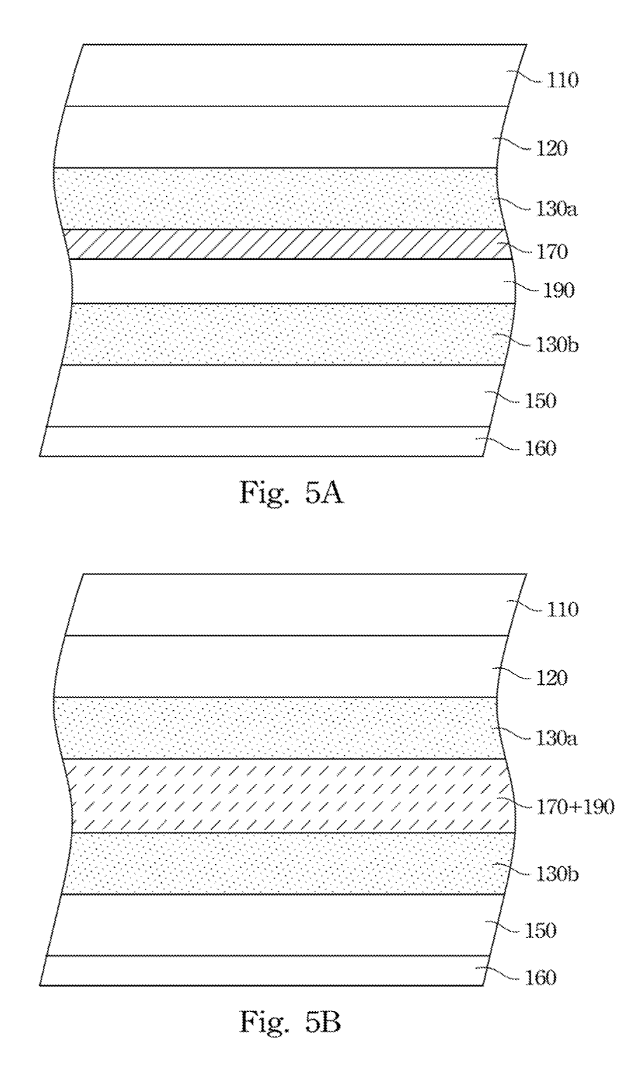

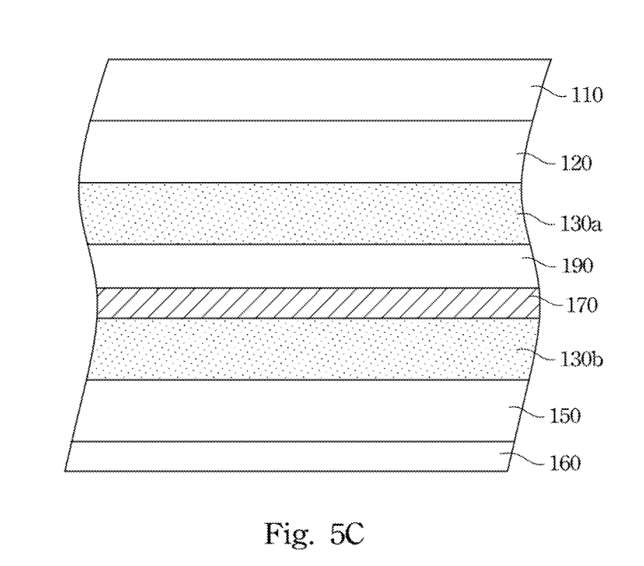

FIGS. 5A-5C are cross-sectional diagrams of photovoltaic cells according to some other embodiments of this invention. In FIGS. 5A-5C, the photovoltaic cells are multijunction cells, and the upconverting luminescent material 170 and a third transparent conductive layer 190 is positioned in the semiconductor layer 130 in FIG. 1B. Therefore, the semiconductor layers 130 in FIGS. 5A-5C are divided into a first semiconductor layer 130a and a second semiconductor layer 130b by the upconverting luminescent material 170 and a third transparent conductive layer 190. According to some embodiments, the upconverting luminescent material 170 can be positioned between the first semiconductor layer 130a and the third transparent conductive layer 190 (in FIG. 5A), in the third transparent conductive layer 190 (in FIG. 5B), or between the third transparent conductive layer 190 and the second semiconductor layer 130b (in FIG. 5C).

Similarly, according to some embodiments, the back reflecting layer 160 in FIGS. 5A-5C can be omitted, since the transparent conductive layer 150 still has some light redirecting function when the difference between the refractive indexes of the semiconductor layer 130b and the transparent conductive layer 150 is compatible.

Accordingly, since the unabsorbed incident light can be upconverted to the light with shorter wavelengths by the upconverting luminescent material and redirected back to the semiconductor layer by the back reflecting layer for re-absorption, the utilization rate of the incident light can be further increased.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, each feature disclosed is one example only of a generic series of equivalent or similar features.

What is claimed is:

1. A solar cell, comprising:
a transparent conductive layer;
at least a semiconductor layer under the transparent conductive layer;
a back metal electrode layer under the semiconductor layer; and
an upconverting luminescent material, wherein the position of the upconverting luminescent material is between the semiconductor layer and the back metal electrode layer, or in the back metal electrode layer.

2. The solar cell of claim 1, wherein the upconverting luminescent material comprising a rare earth metal ion, a dye, or a pigment.

3. The solar cell of claim 2, wherein the rare earth metal ion is Tm³⁺, Eu³⁺, Tb³⁺, Ce³⁺, Pr³⁺, Ho³⁺, Tm³⁺, Yb³⁺, or Er³⁺.

4. A solar cell, comprising:
a first transparent conductive layer;
at least a semiconductor layer under the first transparent conductive layer;
a second transparent conductive layer under the semiconductor layer; and
an upconverting luminescent material, wherein the position of the upconverting luminescent material is between the semiconductor layer and the second transparent conductive layer, or in the second transparent conductive layer.

5. The solar cell of claim 4, wherein the upconverting luminescent material comprising a rare earth metal ion, a dye, or a pigment.

6. The solar cell of claim 5, wherein the rare earth metal ion is Tm³⁺, Eu³⁺, Tb³⁺, Ce³⁺, Pr³⁺, Ho³⁺, Tm³⁺, Yb³⁺, or Er³⁺.

7. The solar cell of claim 4, further comprising a back reflecting layer under the second transparent conductive layer, wherein the position of the upconverting luminescent material is between the semiconductor layer and the second transparent conductive layer, in the second transparent conductive layer, between the second transparent conductive layer and the back reflecting layer, or in the back reflecting layer.

8. The solar cell of claim 7, wherein the back reflecting layer is a reflective encapsulant layer comprising a white pigment.

9. The solar cell of claim 7, wherein the back reflecting layer is a reflective metal layer.

10. A solar cell, composing:
a first transparent conductive layer;
at least a first semiconductor layer under the transparent conductive layer;
a second transparent conductive layer under the first semiconductor layer
at least a second semiconductor layer under the second transparent conductive layer; and
a reflective back electrode layer under the second semiconductor layer; and
an upconverting luminescent material, wherein the position of the upconverting luminescent material is between the first semiconductor layer and the second transparent conductive layer, in the second transparent conductive layer, or between the second transparent conducive layer and the second semiconductor layer.

11. The solar cell of claim 10, wherein the upconverting luminescent material comprising a rare earth metal ion, a dye, or a pigment.

12. The solar cell of claim 10, wherein the reflective back electrode layer comprises a metal electrode layer.

13. The solar cell of claim 10, wherein the reflective back electrode layer comprises a third transparent conductive layer under the second semiconductor layer.

14. The solar cell of claim 13, wherein the reflective back electrode layer further comprises a back reflecting layer under the third transparent conductive layer.

15. A solar cell for receiving an incident light from the top direction, the solar cell comprising:
an upconverting luminescent material below at least a semiconductor layer of the solar cell, such that the incident light, unabsorbed by the semiconductor layer, can be upconverted to a light with shorter wavelengths; and
a back reflecting layer containing the upconverting luminescent material or below the upconverting luminescent material to redirect the light with shorter wavelengths back to the semiconductor layer.

16. The solar cell of claim 15, wherein the upconverting luminescent material comprising a rare earth metal ion, a dye, or a pigment.

17. The solar cell of claim 15, wherein the back reflecting layer comprises a metal layer.

18. The solar cell of claim 15, wherein the back reflecting layer comprises an encapsulant and a white pigment dispersed therein.
